(19) United States
(12) Patent Application Publication
(10) Pub. No.: US 2023/0360893 A1
(43) Pub. Date: Nov. 9, 2023

(54) PLASMA PROCESSING APPARATUS

(71) Applicant: SEMES CO., LTD., Cheonan-si (KR)

(72) Inventor: Dukhyun SON, Cheonan-si (KR)

(73) Assignee: SEMES CO., LTD., Cheonan-si (KR)

(21) Appl. No.: 18/309,285

(22) Filed: Apr. 28, 2023

(30) Foreign Application Priority Data
May 6, 2022 (KR) 10-2022-0056240

(51) Int. Cl. H01F 27/28; H01J 37/32; H01F 27/24

(52) U.S. Cl. CPC H01J 37/32669; H01F 27/24; H01F 27/28; H01J 37/32935; H01J 37/3299; H01J 2237/24564; H01J 2237/24585; H01J 2237/334

(57) ABSTRACT

Provided is a plasma processing apparatus. The plasma processing apparatus includes a chamber configured to isolate a plasma region where plasma is formed from an outside, a core located on the chamber and configured to form a magnetic field in the chamber, and a plurality of coils located adjacent to the core, wherein the core includes a first core having a donut shape, and the plurality of coils include first and second upper outer coils located on a top surface of the first core.

### CROSS-REFERENCE TO RELATED APPLICATION

This application is based on and claims priority under 35 U.S.C. §119 to Korean Pat. Application No. 10-2022-0056240, filed on May 6, 2022, in the Korean Intellectual Property Office, the disclosure of which is incorporated by reference herein in its entirety.

### BACKGROUND

### 1. Field

The disclosure relates to a plasma processing apparatus, and more particularly, to a plasma processing apparatus in which a magnitude of a magnetic field in a chamber in which plasma processing is performed may be adjusted.

### 2. Description of the Related Art

A semiconductor device may be manufactured by forming a certain pattern on a substrate. Deposition and etching in a semiconductor device manufacturing process involve generating plasma from gas and processing a wafer by using the plasma.

Recently, to improve plasma characteristics, an apparatus for applying a magnetic field to a plasma region has been widely used. A magnetic field may limit plasma in a chamber to reduce damage to an inner wall of the chamber due to the plasma. Also, a magnetic field may help to generate and sustain plasma by activating movement of electrons, thereby increasing a plasma density. Also, a magnetic field may improve etching uniformity or deposition uniformity over an entire wafer area by uniformizing a plasma density distribution in the chamber.

### SUMMARY

Provided is a plasma processing apparatus in which a plasma density may be uniformized by adjusting a magnetic field.

Additional aspects will be set forth in part in the description which follows and, in part, will be apparent from the description, or may be learned by practice of the presented embodiments.

According to an aspect of the disclosure, a plasma processing apparatus is provided. The plasma processing apparatus includes a chamber configured to isolate a plasma region where plasma is formed from an outside, a core located on the chamber and configured to form a magnetic field in the chamber, and a plurality of coils located adjacent to the core, wherein the core includes a first core having a donut shape, and the plurality of coils include first and second upper outer coils located on a top surface of the first core.

According to another aspect of the disclosure, a plasma processing apparatus is provided. The plasma processing apparatus includes a chamber configured to isolate a plasma region where plasma is formed from an outside, a core located on the chamber, a plurality of coils located adjacent to the core, a current supply device configured to apply current to the plurality of coils, a plasma measurement device configured to calculate a plasma density by using a voltage of a plasma sheath region generated in the chamber, and a controller configured to control an intensity of a magnetic field formed in the chamber by adjusting current of the current supply device, wherein the core includes a first core located on the chamber and having a donut shape including a hollow portion and a second core located inside the first core and having a cylindrical shape, and the plurality of coils include first and second upper outer coils located on a top surface of the first core.

According to another aspect of the disclosure, a plasma processing apparatus is provided. The plasma processing apparatus includes a chamber configured to isolate a plasma region where plasma is formed from an outside, a core located on the chamber and having a donut shape including a hollow portion, a plurality of coils located adjacent to the core, a current supply device configured to apply current to the plurality of coils, a plasma measurement device configured to calculate a plasma density by using a voltage of a plasma sheath region generated in the chamber, and a controller configured to control an intensity of a magnetic field formed in the chamber by adjusting current of the current supply device, wherein the core includes a first core located on the chamber and having a donut shape including a hollow portion; and a second core located inside the first core and having a cylindrical shape, and the plurality of coils include first and second upper outer coils located on a top surface of the first core, a first helical coil spirally wound around an outer surface of the first core, a second helical coil located in the hollow portion of the first core and spirally wound, and first and second lower outer coils located on a bottom surface of the first core, wherein each of the first and second upper outer coils and the first and second lower outer coils has a ring shape, and the first and second lower outer coils are spaced apart from the first and second upper outer coils with the first core therebetween.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view schematically illustrating a substrate processing apparatus, according to an embodiment;

FIG. 2A is a cross-sectional view schematically illustrating a plasma processing apparatus that performs a semiconductor process on a wafer, according to an embodiment;

FIG. 2B is a view illustrating a plasma sheath region in a chamber, according to an embodiment;

FIG. 3A is a perspective view illustrating an electromagnet, according to an embodiment;

FIG. 3B is a cross-sectional view illustrating the electromagnet, according to an embodiment;

FIG. 3C is a bottom view illustrating the electromagnet, according to an embodiment;

FIG. 4 is a view illustrating a shape of a core, according to an embodiment; and

FIG. 5 is a graph for describing an effect of a plasma processing apparatus, according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure will become more apparent to one of ordinary skill in the art by describing in detail exemplary embodiments thereof with reference to the accompanying drawings. In the drawings, the same reference numerals denote the same members and a repeated description will be omitted.

In the present embodiment, a plasma processing apparatus using a wafer as a plasma processing object and capacitively coupled plasma as a plasma source is described as an example. However, the technical spirit and scope of the disclosure are not limited thereto, and the object may be another type of substrate such as a glass substrate. Also, the capacitively coupled plasma source may be replaced by an inductively coupled plasma source, a microwave plasma source, or a remote plasma source.

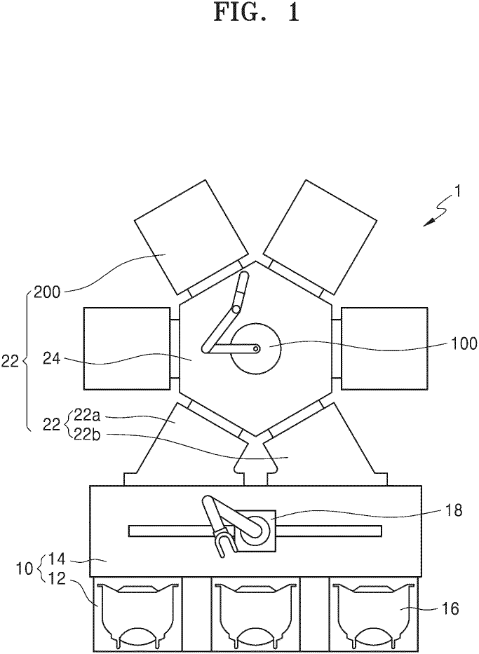

FIG. 1 is a plan view schematically illustrating a substrate processing apparatus 1, according to an embodiment.

Referring to FIG. 1, the substrate processing apparatus 1 includes an equipment front end module 10 and process equipment 20.

The equipment front end module 10 may be mounted in front of the process equipment 20, and transfers a wafer between the process equipment 20 and a container 16 in which wafers are accommodated. The equipment front end module 10 includes a plurality of load ports 12 and a frame 14. The frame 14 is located between the load ports 12 and the process equipment 20. The container 16 in which wafers are accommodated is placed on the load port 12 by a transfer means such as an overhead transfer, an overhead conveyor, or an automatic guided vehicle. The container 16 may be an airtight container such as a front open unified pod. A frame robot 18 for transferring a wafer between the process equipment 20 and the container 16 placed on the load port 12 is provided in the frame 14. A door opener (not shown) for automatically opening/closing a door of the container 16 may be provided in the frame 14. Also, the frame 14 may include a fan filter unit (not shown) for supplying clean air into the frame 14 so that the clean air flows from the top to the bottom in the frame 14.

The process equipment 20 includes a load-lock chamber 22, a transfer chamber 24, and a plasma processing apparatus 200. The transfer chamber 24 has a substantially polygonal shape when viewed from above. The load-lock chamber 22 or the plasma processing apparatus 200 is located on a side surface of the transfer chamber 24.

The load-lock chamber 22 may be located between the transfer chamber 24 and the equipment front end module 10. One or more load-lock chambers 22 are provided. According to an embodiment, two load-lock chambers 22 are provided. Wafers introduced into the process equipment 20 for a process may be accommodated in one of the two load-lock chambers 22, and wafers discharged out from the process equipment 20 after the process is completed may be accommodated in the other of the two load-lock chambers 22. Alternatively, one or more load-lock chambers 22 may be provided, and wafers may be loaded into or unloaded from each of load-lock chambers 22a and 22b.

The inside of the transfer chamber 24 and the plasma processing apparatus 200 is maintained in vacuum, and the inside of the load-lock chamber 22 is switched to vacuum and atmospheric pressure. The load-lock chamber 22 prevents external contaminants from being introduced into the transfer chamber 24 and the plasma processing apparatus 200. A gate valve (not shown) is provided between the load-lock chamber 22 and the transfer chamber 24 and between the load-lock chamber 22 and the equipment front end module 10. The gate valve may be opened/closed between the load-lock chamber 22 and the transfer chamber 24 and between the load-lock chamber 22 and the equipment front end module.

For example, when a wafer is moved between the equipment front end module 10 and the load-lock chamber 22, the gate valve provided between the load-lock chamber 22 and the transfer chamber 24 may be closed. Also, when a wafer is moved between the load-lock chamber 22 and the transfer chamber 24, the gate valve provided between the load-lock chamber 22 and the equipment front end module 10 is closed.

The plasma processing apparatus 200 performs a certain process on a wafer. For example, the plasma processing apparatus 200 performs a process by using plasma such as ashing, deposition, etching, or cleaning. One or more plasma processing apparatus 200 are provided along sides of the transfer chamber 24. When a plurality of plasma processing apparatuses 200 are provided, the plasma processing apparatuses 200 may perform the same process on wafers. Optionally, when a plurality of plasma processing apparatuses 200 are provided, the plasma processing apparatuses 26 may perform different processes on wafers.

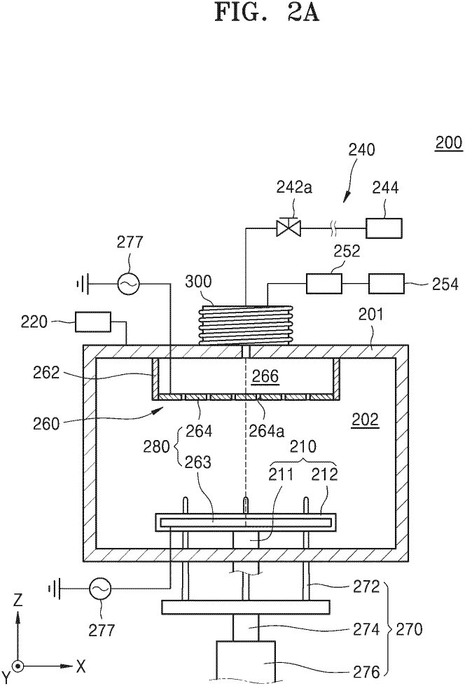

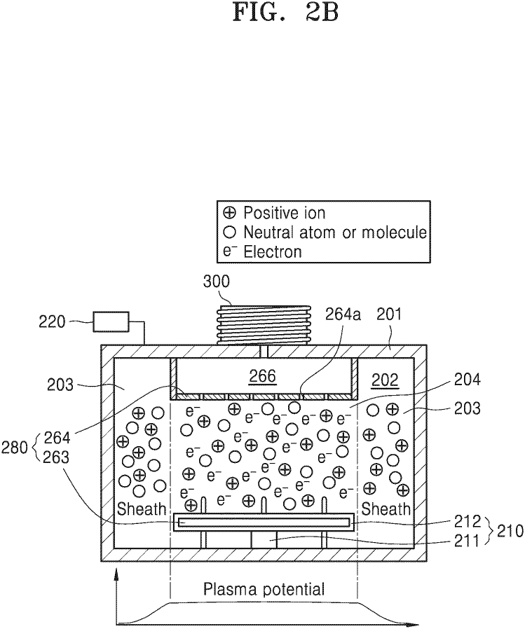

FIG. 2A is a cross-sectional view schematically illustrating the plasma processing apparatus 200 that performs a semiconductor process on a wafer, according to an embodiment.

Referring to FIG. 2A, the plasma processing apparatus 200 may include a chamber 201, a support device 210, a gas supply device 240, a shower head 260, a plasma source 280, and an electromagnet 300.

The chamber 201 may have a cylindrical shape having an inner space 202 in which a process is performed. The chamber 201 may be configured to isolate a plasma region where plasma is formed from the outside. Also, an exhaust pipe (not shown) through which byproducts generated during a process are discharged is connected to a bottom surface of the chamber 201. A pump (not shown) for maintaining the inside of the chamber 201 at a process pressure during a process and a valve for opening/closing a passage in the exhaust pipe are provided in the exhaust pipe.

The support device 210 includes a support plate 212 that supports a wafer during a process. The support device 210 has a substantially disk shape. A support shaft 211 that is rotatable by a driver 276 is fixedly coupled to a bottom surface of the support plate 212. A wafer may rotate during a process. The support device 210 may fix a wafer by using a method such as an electrostatic force or mechanical clamping.

The gas supply device 240 supplies process gas into the chamber 201. The gas supply device 240 includes a gas supply pipe 242a that connects a gas supply source 244 to the chamber 201. A valve for opening/closing an inner passage is provided in the gas supply pipe 242a.

The shower head 260 uniformly distributes process gas introduced into the chamber 201 to an upper portion of the support plate 212. The shower head 260 may be located in the inner space of the chamber 201. The shower head 260 may face the support device 210. The shower head 260 includes a side wall 262 having an annular shape and a spray plate 264 having a disk shape. The side wall 262 of the shower head 260 is fixedly coupled to the chamber 201 to protrude downward from an upper wall of the chamber 201. The spray plate 264 is fixedly coupled to a lower end of the side wall. A plurality of spray holes 264a are formed in the entire area of the spray plate 264. Process gas is introduced into a space 266 provided by the shower head 260 and the chamber 201 and then is sprayed onto a wafer through the spray holes 264a.

A lift-pin assembly 270 loads a wafer on the support plate 212 or unloads the wafer from the support plate 212. The lift-pin assembly 270 includes a lift-pin 272, a base plate 274, and the driver 276. Three lift-pins 272 are provided, and are fixedly provided on the base plate 274 to move along with the base plate 274. The base plate 274 has a disk shape, and is provided under the support plate 212 in the chamber 201 or outside the chamber 201. The base plate 274 is vertically moved by the driver 276 such as a hydropneumatic cylinder or a motor. The lift-pins 272 are located to correspond to vertices of a substantially equilateral triangle when viewed from above. Through-holes vertically passing through the support plate 212 are formed in the support plate 212. Each lift-pin 272 is inserted into each through-hole and vertically moved through the through-hole. Each lift-pin 272 may have a long rod shape. An upper end of the lift-pin 272 has an upwardly convex shape.

The plasma source 280 generates plasma from process gas supplied to an upper portion of the support plate 212. Capacitively coupled plasma is used as the plasma source 280.

The plasma processing apparatus 200 may include the spray plate 264, a lower electrode 263, and a power supply. The spray plate 264 of the shower head 260 may be an upper electrode for supplying power for generating plasma. The lower electrode 263 may be embedded in the support plate 212.

A first power supply 277 may be configured to supply source power for generating plasma to the spray plate 264. A second power supply 279 may be configured to supply bias power for accelerating ions included in the plasma to the lower electrode 263. According to embodiments, a frequency of current or a voltage of power supplied by the first and second power supplies 277 and 279 may be in a radio frequency (RF) range.

In another example, the second power supply 279 may be omitted, and the first power supply 277 may be configured to provide source power and bias power to the lower electrode 263. In another example, the first power supply 277 may be omitted, and the second power supply 279 may be configured to provide source power and bias power to the lower electrode 263.

The electromagnet 300 may be located on the chamber 201. The electromagnet 300 may be configured to apply a magnetic field into the chamber 201. Accordingly, the electromagnet 300 may provide a magnetic field to a region where plasma is formed.

The electromagnet 300 may include a core and a plurality of coils. The core may be located on the chamber 201, and may be configured to form a magnetic field in the chamber 201. The core may include a first core and/or a second core. Also, the plurality of coils may be located adjacent to the core, and may be configured to form a magnetic field in the chamber 201. The electromagnet 300 may receive current from a current supply device 252 to form a magnetic field in the inner space 202 of the chamber 201.

Also, the plasma processing apparatus 200 may include a controller 254 for controlling an intensity of a magnetic field formed in the chamber 201 by adjusting current of the current supply device 252. The controller 254 may improve plasma uniformity in the chamber 201 (more specifically, uniformity of a plasma density along a radius from the center of the chamber) by adjusting an intensity of a magnetic field in the chamber 201. Also, the controller 254 may control the current supply device 252 to apply current, flowing through the plurality of coils, in a pulse form.

FIG. 2B is a view illustrating a plasma sheath region in a chamber, according to an embodiment.

Referring to FIG. 2B, the plasma processing apparatus 200 may form plasma in the inner space 202 of the chamber 201. Plasma is ionized gas, and is a fourth state after solid, liquid, and gas in which positive ions, neutral atoms, and free electrons exist separately. Because of free electrons, plasma has high electrical conductivity and very high reactivity to an electromagnetic field.

Accordingly, a plasma region may be defined within a set radius from the center of the chamber 201, and a plasma sheath region 203 may be defined outside the set radius. The plasma sheath region 203 is a region where the number of positive ions and neutrons is greater than that in the plasma region. The plasma region may be horizontally surrounded by the plasma sheath region 203. Also, the plasma sheath region 203 may exist not only between plasma and a wall surface of the chamber 201 but also between the spray plate 264 and the lower electrode 263. In this case, the plasma region may be three-dimensionally surrounded by the plasma sheath region 203. The plasma region may include a region 204. The plasma sheath region 203 may be horizontally spaced apart from a wafer, and the wafer may be located in the region 204 of FIG. 2B.

A graph below the chamber 201 shows a plasma potential in the inner space 202 of the chamber 201. The horizontal axis represents a radius from the center of the chamber 201, and the vertical axis represents a plasma potential. The horizontal axis and the vertical axis are represented in arbitrary units (hereinafter, a.u.).

A plasma potential may be sharply reduced in the plasma sheath region 203. A plasma density may be calculated based on, for example, a potential difference (e.g., a direct current (DC) bias) generated due to the plasma sheath region 203.

The plasma processing apparatus 200 may further include a plasma measurement device 220 for calculating a plasma density by using a voltage of the plasma sheath region 203 generated in the inner space 202 of the chamber 201. The plasma measurement device 220 may be configured to measure a DC bias generated from the chamber 201. The plasma measurement device 220 may be configured to calculate a plasma density based on a voltage of the chamber 201. The controller 254 may control current applied to a plurality of coils based on the plasma density.

In another embodiment, the plasma processing apparatus 200 may determine a plasma density by determining a cutoff frequency of plasma for microwaves, based on a microwave band spectrum of a forward transmission gain of the plasma.

In another example, the plasma processing apparatus 200 may measure an optical signal generated from plasma, and may perform Abel transformation on a measurement result, to calculate a relative value profile of a plasma density along a radius in the chamber 201.

According to the disclosure, a density of plasma formed in the inner space 202 of the chamber may be measured in real time by using the plasma measurement device 220, and the plasma density may be uniformized by adjusting an intensity distribution of a magnetic field applied to the inside of the chamber 201 based on the plasma density.

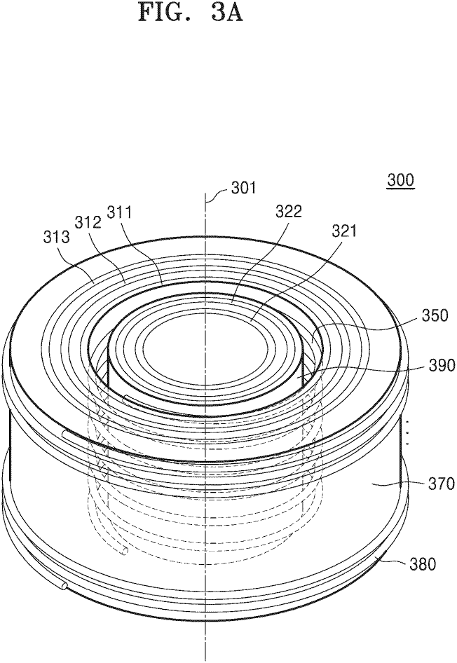

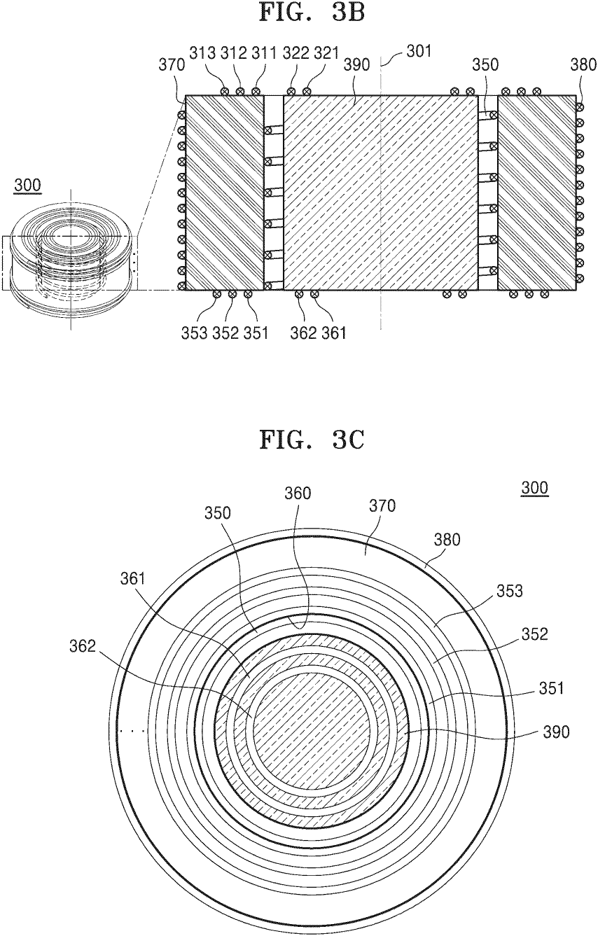

FIG. 3A is a perspective view illustrating the electromagnet 300, according to an embodiment. FIG. 3B is a cross-sectional view illustrating the electromagnet 300, according to an embodiment. FIG. 3C is a bottom view illustrating the electromagnet, according to an embodiment.

Referring to FIGS. 2A, and 3A to 3C, a plasma processing apparatus (e.g., 200 of FIG. 2A) may include first and second cores 370 and 390, first to third upper outer coils 311, 312, and 313, first and second upper inner coils 321 and 322, first to third lower outer coils 351, 352, and 353, first and second lower inner coils 361 and 362, a first helical coil 380 and a second helical coil 350.

The first and second cores 370 and 390, the first to third upper outer coils 311, 312, and 313, the first and second upper inner coils 321 and 322, the first to third lower outer coils 351, 352, and 353, the first and second lower inner coils 361 and 362, the first helical coil 380, and the second helical coil 350 may constitute the electromagnet.

Any one of pulse current, alternating current (AC) current, and DC current may be applied to the first core 370, the first to third upper outer coils 311, 312, and 313, the first and second upper inner coils 321 and 322, the first to third lower outer coils 351, 352, and 353, the first and second lower inner coils 361 and 362, the first helical coil 380, and the second helical coil 350. According to embodiments, the first core 370, the first to third upper outer coils 311, 312, and 313, the first and second upper inner coils 321 and 322, the first to third lower outer coils 351, 352, and 353, the first and second lower inner coils 361 and 362, the first helical coil 380, and the second helical coil 350 may be configured to form a magnetic field based on applied current, together with the first and second cores 370 and 390.

The first core 370 may have a donut shape, and a central axis 301 of the first core 370 may match a central axis of the chamber 201. Also, the second core 390 may be located inside the first core 370, and may have a cylindrical shape, and a central axis of the second core 390 may match the central axis 301 of the first core. The first core 370 may horizontally surround the second core 390. The first core 370 and the second core 390 may be radially symmetric with respect to the center of the chamber 201.

The first and second cores 370 and 390 may include a ferromagnetic material such as soft iron. The first and second cores 370 and 390 may increase an intensity of a magnetic field formed by the first and second cores 370 and 390, the first to third upper outer coils 311, 312, and 313, the first and second upper inner coils 321 and 322, the first to third lower outer coils 351, 352, and 353, the first and second lower inner coils 361 and 362, the first helical coil 380, and the second helical coil 350. The first and second cores 370 may support the first and second cores 370 and 390, the first to third upper outer coils 311, 312, and 313, the first and second upper inner coils 321 and 322, the first to third lower outer coils 351, 352, and 353, the first and second lower inner coils 361 and 362, the first helical coil 380, and the second helical coil 350 to maintain their wound shapes.

Also, the first to third upper outer coils 311, 312, and 313 may be located on a top surface of the first core 370. The first to third upper outer coils 311, 312, and 313 may overlap the first core 370 in a direction of the central axis 301. The first to third upper outer coils 311, 312, and 313 may each have a ring shape. The centers of the first to third upper outer coils 311, 312, and 313 may be substantially the same.

A radius of the first upper outer coil 311 may be less than a radius of the second upper outer coil 312. A radius of the second upper outer coil 312 may be less than a radius of the third upper outer coil 313. A radius of each of the first to third upper outer coils 311, 312, and 313 may be equal to or greater than an inner diameter of the first core 370 and equal to or less than an outer diameter of the first core 370.

The first to third upper outer coils 311, 312, and 313 may be spaced apart from each other. The first to third upper outer coils 311, 312, and 313 may be electrically insulated from each other. Accordingly, different currents may be applied to the first to third upper outer coils 311, 312, and 313. That is, the first to third upper outer coils 311, 312, and 313 may be individually driven.

The first and second upper inner coils 321 and 322 may be located on a top surface of the second core 390. The first and second upper inner coils 321 and 322 may overlap the first core 370 in the direction of the central axis 301. The first and second upper inner coils 321 and 322 may each have a ring shape. The centers of the first and second upper inner coils 321 and 322 may be substantially the same. The centers of the first and second upper inner coils 321 and 322 may be substantially the same as the centers of the first to third upper outer coils 311, 312, and 313.

A radius of the first upper inner coil 321 may be less than a radius of the second upper inner coil 322. A radius of each of the first and second upper inner coils 321 and 322 may be less than a radius of the second core 390. A radius of each of the first and second upper inner coils 321 and 322 may be less than a radius of the first upper outer coil 311.

The first and second upper inner coils 321 and 322 may be spaced apart from each other. The first and second upper inner coils 321 and 322 may be electrically insulated from each other. Accordingly, different currents may be applied to the first and second upper inner coils 321 and 322. That is, the first and second upper inner coils 321 and 322 may be individually driven.

The first to third lower outer coils 351, 352, and 353 may be located on a bottom surface of the first core 370. The first to third lower outer coils 351, 352, and 353 may overlap the first core 370 in the direction of the central axis 301. The first to third lower outer coils 351, 352, and 353 may be spaced apart from the first to third upper outer coils 311, 312, and 313 with the first core 370 therebetween. The first to third lower outer coils 351, 352, and 353 may each have a ring shape. The centers of the first to third lower outer coils 351, 352, and 353 may be substantially the same.

A radius of the first lower outer coil 351 may be less than a radius of the second lower outer coil 352. A radius of the second lower outer coil 352 may be less than a radius of the third lower outer coil 353. A radius of each of the first to third lower outer coils 351, 352, and 353 may be equal to or greater than an inner diameter of the first core 370 and equal to or less than an outer diameter of the first core 370.

The first to third lower outer coils 351, 352, and 353 may be spaced apart from each other. The first to third lower outer coils 351, 352, and 353 may be electrically insulated from each other. Accordingly, different currents may be applied to the first to third lower outer coils 351, 352, and 353. That is, the first to third lower outer coils 351, 352, and 353 may be individually driven.

The first and second lower inner coils 361 and 362 may be located on a bottom surface of the second core 390. The first and second lower inner coils 361 and 362 may overlap second core 390 in the direction of the central axis 301. The first and second lower inner coils 361 and 362 may be spaced apart from the first and second upper inner coils 321 and 322 with the second core 390 therebetween. The first and second lower inner coils 361 and 362 may each have a ring shape. The centers of the first and second lower inner coils 361 and 362 may be substantially the same. The centers of the first and second lower inner coils 361 and 362 may be substantially the same as the centers of the first to third lower outer coils 351, 352, and 353.

A radius of the first lower inner coil 361 may be less than a radius of the second lower inner coil 362. A radius of each of the first and second lower inner coils 361 and 362 may be less than a radius of the second core 390. A radius of each of the first and second lower inner coils 361 and 362 may be less than a radius of the first lower outer coil 351.

The first and second lower inner coils 361 and 362 may be spaced apart from each other. The first and second lower inner coils 361 and 362 may be electrically insulated from each other. Accordingly, different currents may be applied to the first and second lower inner coils 361 and 362. That is, the first and second lower inner coils 361 and 362 may be individually driven.

The first helical coil 380 may surround the first core 370. The first helical coil 380 may be spirally wound around an outer surface of the first core 370. The second helical coil 350 may surround the second core 390. The second helical coil 350 may be spirally wound around a side surface of the second core 390.

According to embodiments, the number of turns of the first helical coil 380 may be greater than the number of turns of the second helical coil 350. Accordingly, when current of the same magnitude flows through the first helical coil 380 and the second helical coil 350, an intensity of a magnetic field induced by the first helical coil 380 may be greater than an intensity of a magnetic field induced by the second helical coil 350.

According to embodiments, the first helical coil 380 and the second helical coil 350 may be wound in the same direction. For example, when viewed from above, the first helical coil 380 and the second helical coil 350 may be wound clockwise or counterclockwise.

According to embodiments, the first helical coil 380 and the second helical coil 350 may be wound in opposite directions. For example, when viewed from above, the first helical coil 380 may be wound clockwise and the second helical coil 350 may be wound counterclockwise, or the first helical coil 380 may be wound counterclockwise and the second helical coil 350 may be wound clockwise.

According to an experimental example, it is found that, when a magnetic field is applied to a plasma region, a plasma density varies in proportion to an intensity of the magnetic field. In general, a magnetic field formed by a ring-shaped coil such as the first to third upper outer coils 311, 312, and 313 and the first to third lower outer coils 351, 352, and 353 has a maximum intensity at the center of the ring.

According to embodiments, the first core 370 having a donut shape may mainly limit a magnetic flux generated from the first to third upper outer coils 311, 312, and 313, the first to third lower outer coils 351, 352, and 353, and the first helical coil 380 in the first core 370. The first core 370, the first to third upper outer coils 311, 312, and 313, the first to third lower outer coils 351, 352, and 353, and the first helical coil 380 may form a magnetic field having a greater intensity at an edge portion than at a central portion of the chamber 201. Accordingly, uniformity of a plasma density in a radial direction may be improved.

Furthermore, the first core 370 having a donut shape may offset part of a magnetic flux generated from the first to third upper outer coils 311, 312, and 313, the first to third lower outer coils 351, 352, and 353, and the second helical coil 350 and passing through the central portion of the chamber 201. Accordingly, uniformity of a plasma density in a radial direction may be further improved.

As describe above, the first core 370, the first to third upper outer coils 311, 312, and 313, the first and second upper inner coils 321 and 322, the first to third lower outer coils 351, 352, and 353, the first and second lower inner coils 361 and 362, the first helical coil 380, and the second helical coil 350 may be electrically insulated from each other and may be individually driven.

The controller 254 may control an intensity and a direction of current applied to the first core 370, the first to third upper outer coils 311, 312, and 313, the first and second upper inner coils 321 and 322, the first to third lower outer coils 351, 352, and 353, the first and second lower inner coils 361 and 362, the first helical coil 380, and the second helical coil 350. Accordingly, a magnetic field distribution along a radius in the chamber 201 may be finely adjusted, and controllability of a magnetic field distribution and uniformity of a plasma density may be improved.

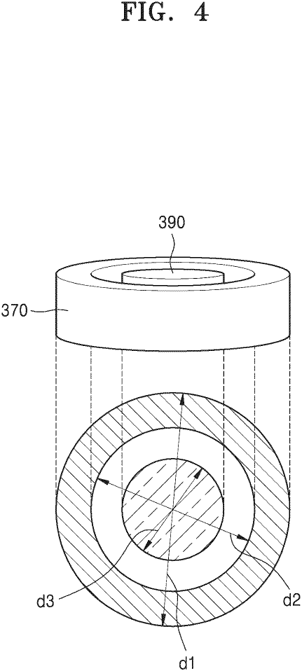

FIG. 4 is a view illustrating a shape of a core, according to an embodiment.

Referring to FIG. 4, the electromagnet 300 may include the first core 370 and the second core 390, and the second core 390 may be located inside the first core 370. The first core 370 may have a donut shape, and upper and lower magnetic poles of the first core 370 may be different from each other. For example, an upper end 512 of the first core 370 may be an S-pole, and a lower end 514 of the first core 370 may be an N-pole. In another example, the upper end 512 of the first core 370 may be an N-pole, and the lower end 514 may be an S-pole.

An inner diameter of the first core 370 may range from about 50 mm to about 200 mm, and an outer (major) diameter of the first core 370 may range from about 60 mm to about 240 mm. Also, the second core 390 may have a diameter less than an inner diameter of the first core 370. For example, a diameter of the second core 390 may range from about 30 mm to about 45 mm, and when an inner diameter of the first core 370 is greater than a diameter of the second core 390, the first core 370 may have a diameter of 45 mm or more.

An outer diameter of the first core 370 may be equal to or less than a diameter of a wafer. A diameter of a wafer may be, for example, about 150 mm, about 200 mm, about 450 mm, or more. A diameter of the first core 370 and/or a diameter of the second core 390 may vary according to the diameter of the wafer,

The first core 370 may have a donut shape. When the first core has a donut shape, the first core may radially symmetrically affect a magnetic field with respect to the center of the wafer. Also, the center of the first core 370 may be vertically aligned with the center of the wafer. In an embodiment, an intensity of a magnetic field formed by the first and second cores 370 and 390 in the inner space 202 of the chamber 201 may range from 3,000 Gauss to 10,000 Gauss.

When the current supply device 252 applies current to the plurality of coils, a magnetic field may have a maximum intensity at the center of the wafer. Also, it is found that, as an intensity of current applied to the plurality of coils increases, a magnitude of a magnetic field formed on a surface of the wafer generally increases.

The controller 254 may be configured to adjust an intensity of a magnetic field of an electromagnet, according to a progress degree of a semiconductor process on the wafer. The controller 254 may transmit a signal to the current supply device 252, and may adjust a magnitude and/or a direction of current applied to the plurality of coils. Also, the controller 254 may control the current supply device 252 to provide current applied to the plurality of coils in a pulse form. The controller 254 may control a pulse frequency of current, a duty ratio, and a voltage level, and thus, may control an intensity of a magnetic field.

The controller 254 may adjust an intensity of current by controlling the current supply device 252. For example, to form a relatively strong magnetic field, the controller 254 may increase an intensity of current applied to the plurality of coils of the current supply device 252. In contrast, to form a relatively weak magnetic field, the controller 254 may reduce an intensity of current applied to the plurality of coils. Also, the controller 254 may individually control currents applied to the plurality of coils. For example, the controller 254 may adjust current applied to a second upper outer coil to be larger than current applied to a first upper outer coil. The current may refer to a plurality of currents applied to the plurality of coils.

Also, when a plasma density measured by the plasma measurement device 220 exceeds a threshold value, the controller 254 may control a flow of current so that directions of magnetic fields formed by current flowing through a third coil and a fourth coil are opposite to each other. The threshold value may refer to an amount exceeding an appropriate range of a plasma density required to perform a semiconductor process. The threshold value may vary according to a type of gas used in the semiconductor process.

The controller 254 may be implemented as hardware, firmware, software, or any combination thereof. For example, the controller 254 may be a computing device such as a workstation computer, a desktop computer, a laptop computer, or a tablet computer. For example, the controller 254 may include a memory device such as a read-only memory (ROM) or a random-access memory (RAM), and a processor configured to perform a certain operation and algorithm, such as a microprocessor, a central processing unit (CPU) or a graphics processing unit (GPU). Also, the controller 254 may include a receiver and a transmitter for receiving and transmitting an electrical signal.

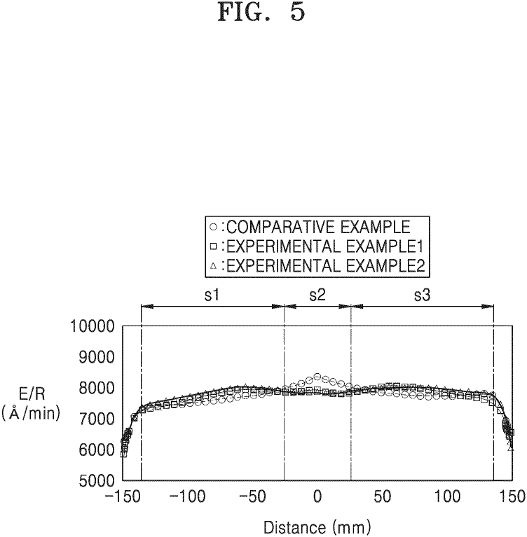

FIG. 5 is a graph for describing an effect of a plasma processing apparatus, according to embodiments.

The graph of FIG. 5 shows an etching amount from a central portion s21 to edges s1 and s3 of a wafer. In more detail, the vertical axis of FIG. 5 represents an etch rate (E/R) of the wafer, and the horizontal axis represents a distance from the central portion s2 of the wafer. FIG. 5 shows an etch rate due to plasma in the chamber 201 (see FIG. 2) in Comparative Example, Experimental Example 1, and Experimental Example 2, and the etch rate is proportional to a plasma density. Accordingly, a change in a plasma density may be known from a change in the etch rate shown in FIG. 5.

Comparative Example corresponds to a case where a magnetic field is formed by using a general cylindrical core and an etching process is performed in the chamber 201, and Experimental Example 1 and Experimental Example 2 correspond to a case where a magnetic field is formed by using a core of the disclosure and an etching process is performed in the chamber 201.

Referring to Comparative Example of FIG. 5, it is found that an etch rate in the chamber 201 is high at the central portion s2 of the wafer and is low at the edges s1 and s3. It is found that, because an intensity of a magnetic field formed by the cylindrical core is the highest at the central portion s2 of the wafer, a plasma density is the highest at the central portion s2 and decreases toward the edges s1 and s3. Accordingly, it is found that there is etch rate distribution non-uniformity between the central portion s2 and the edges s1 and s3.

Referring to Experimental Example 1 and Experimental Example 2, it is found that an etch rate in the chamber 201 is generally uniform compared to Comparative Example. Because the plasma processing apparatus 200 using the donut-shaped core may form a magnetic field having a greater intensity at the edges s1 and s3 than at the central portion s2 of the chamber 201, uniformity of a plasma density in a radial direction is improved. Accordingly, the reliability of a semiconductor etching process using the disclosure may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the disclosure as defined by the following claims.

What is claimed is:

1. A plasma processing apparatus comprising:
a chamber configured to isolate a plasma region where plasma is formed from an outside;
a first core located on the chamber and having a donut shape comprising a hollow portion; and
first and second upper outer coils located on a top surface of the first core.

2. The plasma processing apparatus of claim 1, further comprising:
a first helical coil spirally wound around an outer surface of the first core; and
a second helical coil located in the hollow portion of the first core and spirally wound.

3. The plasma processing apparatus of claim 2, wherein a number of turns of the first helical coil is greater than a number of turns of the second helical coil.

4. The plasma processing apparatus of claim 1, wherein
each of the first and second upper outer coils has a ring shape, and
centers of the first and second upper outer coils match each other.

5. The plasma processing apparatus of claim 1, further comprising first and second lower outer coils located on a bottom surface of the first core,
wherein each of the first and second lower outer coils has a ring shape, and
centers of the first and second lower outer coils match each other.

6. The plasma processing apparatus of claim 5, wherein the first and second lower outer coils are spaced apart from the first and second upper outer coils with the first core therebetween.

7. The plasma processing apparatus of claim 5, wherein a radius of the first upper outer coil is less than a radius of the second upper outer coil, and a radius of the first lower outer coil is less than a radius of the second lower outer coil.

8. The plasma processing apparatus of claim 5, wherein the first and second upper outer coils and the first and second lower inner outer coils are spaced apart from each other, and are electrically insulated.

9. The plasma processing apparatus of claim 5, wherein the first and second upper outer coils and the first and second lower outer coils overlap the first core in a direction of a central axis of the first core.

10. The plasma processing apparatus of claim 1, further comprising:
a second core located in the hollow portion of the first core, and having a cylindrical shape;
first and second upper inner coils located on a top surface of the second core; and
first and second lower inner coils located on a bottom surface of the second core.

11. The plasma processing apparatus of claim 10, wherein
centers of the first core and the second core match each other, and
the first and second lower inner coils are spaced apart from the first and second upper inner coils with the second core therebetween.

12. The plasma processing apparatus of claim 11, wherein
each of the first and second upper inner coils and the first and second lower inner coils has a ring shape, and
a radius of the first upper inner coil is less than a radius of the second upper inner coil, and a radius of the first lower inner coil is less than a radius of the second lower inner coil.

13. A plasma processing apparatus comprising:
a chamber configured to isolate a plasma region where plasma is formed from an outside;
a core located on the chamber;
a plurality of coils located adjacent to the core;
a current supply device configured to apply current to the plurality of coils;
a plasma measurement device configured to calculate a plasma density by using a voltage of a plasma sheath region generated in the chamber; and
a controller configured to control an intensity of a magnetic field formed in the chamber by adjusting current of the current supply device,
wherein the core comprises a first core located on the chamber and having a donut shape comprising a hollow portion and a second core located inside the first core and having a cylindrical shape, and
the plurality of coils comprise first and second upper outer coils located on a top surface of the first core.

14. The plasma processing apparatus of claim 13, wherein the plasma measurement device is further configured to measure a direct current (DC) bias of the plasma sheath region, and calculate a plasma density based on the DC bias.

15. The plasma processing apparatus of claim 13, wherein the controller is further configured to control the current supply device to apply current in a pulse form to each of the plurality of coils.

16. The plasma processing apparatus of claim 13, wherein the controller is further configured to, when the plasma density is greater than a threshold value, reduce the current applied to the plurality of coils, and when the plasma density is equal to or less than the threshold value, increase the current applied to the plurality of coils.

17. The plasma processing apparatus of claim 13, further comprising:
a first helical coil spirally wound around an outer surface of the first core; and
a second helical core located in the hollow portion of the first core and spirally wound.

18. A plasma processing apparatus comprising:
a chamber configured to isolate a plasma region where plasma is formed from an outside;
a core located on the chamber and having a donut shape comprising a hollow portion;
a plurality of coils located adjacent to the core;
a current supply device configured to apply current to the plurality of coils;
a plasma measurement device configured to calculate a plasma density by using a voltage of a plasma sheath region generated in the chamber; and
a controller configured to control an intensity of a magnetic field formed in the chamber by adjusting current of the current supply device,
wherein the core comprises:
a first core located on the chamber and having a donut shape comprising a hollow portion; and
a second core located inside the first core and having a cylindrical shape, and
the plurality of coils comprise:
first and second upper outer coils located on a top surface of the first core;
a first helical coil spirally wound around an outer surface of the first core;
a second helical coil located in the hollow portion of the first core and spirally wound; and
first and second lower outer coils located on a bottom surface of the first core,
wherein each of the first and second upper outer coils and the first and second lower outer coils has a ring shape, and the first and second lower outer coils are spaced apart from the first and second upper outer coils with the first core therebetween.

19. The plasma processing apparatus of claim 18, wherein
a diameter of the second core ranges from 30 mm to 45 mm, and
an inner diameter of the first core ranges from 50 mm to 200 mm, and an outer diameter of the first core ranges from 60 mm to 240 mm.

20. The plasma processing apparatus of claim 18, wherein a magnitude of a magnetic field formed in the chamber by the core and the plurality of coils ranges from 3,000 Gauss to 10,000 Gauss.
